(19) United States
(12) Patent Application Publication
(10) Pub. No.: US 2006/0284549 A1
(43) Pub. Date: Dec. 21, 2006

(54) Light-emitting element, method of manufacturing the same and display substrate having the same

(75) Inventor: Dong-Won Lee, Seongnam-si (KR)

Correspondence Address: DLA PIPER RUDNICK GRAY CARY US, LLP, 2000 UNIVERSITY AVENUE, E. PALO ALTO, CA, 94303-2248, US

(73) Assignee: Samsung Electronics Co., Ltd.

(21) Appl. No.: 11/472,170

(22) Filed: Jun. 21, 2006

(30) Foreign Application Priority Data
Jun. 21, 2005 (KR) 10-2005-53418

(51) Int. Cl. H05B 33/00; H01L 51/50

(52) U.S. Cl. 313/503; 313/504; 313/512; 445/24

(57) ABSTRACT

A light-emitting element that improves reliability and manufacturing efficiency is presented. The light-emitting element includes a first electrode, a bank, a light-emitting layer and a second electrode. The first electrode is formed on a base substrate. The bank is formed on a part of the first electrode that is in a light-emitting area. The bank has a first thickness. The light-emitting layer is formed on the first electrode of the light-emitting area. The second electrode is formed on the light-emitting layer. The second electrode has a second thickness that is thicker than the first thickness of the bank. Thus, the second electrode is thicker than the bank.

### CROSS REFERENCE TO RELATED APPLICATIONS

This application relies for priority upon Korean Patent Application No. 2005-53418 filed on Jun. 21, 2005, the content of which is herein incorporated by reference in its entirety.

### BACKGROUND OF THE INVENTION

1. Field of the Invention

The present invention relates to a light-emitting element, a method of manufacturing the light-emitting element and a display substrate having the light-emitting element. More particularly, the present invention relates to a light-emitting element capable of improving a manufacturing efficiency and reliability, a method of manufacturing the light-emitting element and a display substrate having the light-emitting element.

2. Description of the Related Art

Generally, an electroluminescent display substrate includes a plurality of electroluminescent elements that are arranged into pixels. Each of the electroluminescent elements includes two electrodes and an electroluminescent layer disposed between the two electrodes. The electroluminescent layer emits light in response to an electric field generated between the two electrodes. At least one of the two electrodes is transparent, allowing the light emitted from the electroluminescent layer to escape the electroluminescent display substrate, thereby displaying an image.

Each of the electroluminescent elements includes an anode formed on a base substrate, an electroluminescent layer formed on the anode of a light-emitting area and a cathode formed on the electroluminescent layer. A bank is formed on the anode and defines the light-emitting area. The anode and the cathode correspond to a pixel electrode and a common electrode, respectively.

The bank is relatively thick, and the cathode is relatively thin. As a result, the cathode may be discontinuous at a stepped portion of the bank. A discontinuity in the cathode formation is a defect in the electroluminescent element, and also a defect in the electroluminescent display substrate built with the defective electroluminescent elements.

### SUMMARY OF THE INVENTION

The present invention obviates the above problems and thus the present invention provides a light-emitting element capable of improving a manufacturing efficiency and a reliability. The present invention also provides a method of manufacturing the above-mentioned light-emitting element. The present invention also provides a display substrate having the above-mentioned light-emitting element.

In one aspect of the present invention, a light-emitting element includes a first electrode, a bank, a light-emitting layer and a second electrode. The first electrode is formed on a base substrate. The bank is formed on the first electrode to define a light-emitting area. The bank has a first thickness. The light-emitting layer is formed on a part of the first electrode that is in the light-emitting area. The second electrode is formed on the light-emitting layer. The second electrode has a second thickness that is thicker than the first thickness of the bank.

In another aspect of the present invention, a light-emitting element includes a first electrode, a bank, a light-emitting layer and a second electrode. The first electrode is formed on a base substrate. The bank is formed on the first electrode to define a light-emitting area. The bank includes a negative type photoresist. The light-emitting layer is formed on a part of the first electrode that is in the light-emitting area. The second electrode is formed on the light-emitting layer.

In yet another aspect, the present invention is a method of manufacturing a light-emitting element. The method entails forming a first electrode on a base substrate, forming a bank having a first thickness on the first electrode to define a light-emitting area, and forming a light-emitting layer on a part of the first electrode that is in the light-emitting area. A second electrode having a second thickness that is thicker than the first thickness of the bank is formed on the light-emitting layer.

In yet another aspect, the present invention is a display substrate having a pixel region defined by a source line, a bias voltage line and neighboring gate lines. The display substrate includes a switching element, a first electrode, a bank, a light-emitting layer and a second electrode. The switching element is electrically connected to the bias voltage line. The first electrode is formed in the pixel region and electrically connected to the switching element. The bank is formed on a portion of the first electrode to define a light-emitting area in the pixel region. The bank has a first thickness. The light-emitting layer is formed on the first electrode in the light-emitting area. The second electrode is formed on the light-emitting layer. The second electrode has a second thickness that is thicker than the first thickness of the bank.

According to the above, the second electrode is formed to have a thicker thickness than that of the bank by using a metal nanopaste, so that a defect of the second electrode may be prevented.

### BRIEF DESCRIPTION OF THE DRAWINGS

The above and other advantages of the present invention will become readily apparent by reference to the following detailed description when considered in conjunction with the accompanying drawings wherein:

FIG. 1 is a layout illustrating a portion of an electroluminescent display substrate according to an example embodiment of the present invention;

FIG. 2 is a cross-sectional view taken along a line I-I′ in FIG. 1;

FIGS. 3 to 8 are cross-sectional views illustrating a method-of manufacturing the electroluminescent display substrate shown in FIG. 2; and

FIG. 9 is a cross-sectional view illustrating an electroluminescent display substrate according to another embodiment of the present invention.

### DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, region or substrate is referred to as being “on” or “onto” another element, it may be directly on the other element or intervening elements may also be present. In contrast, when an element is referred to as being “directly on” another element, there are no intervening elements present.

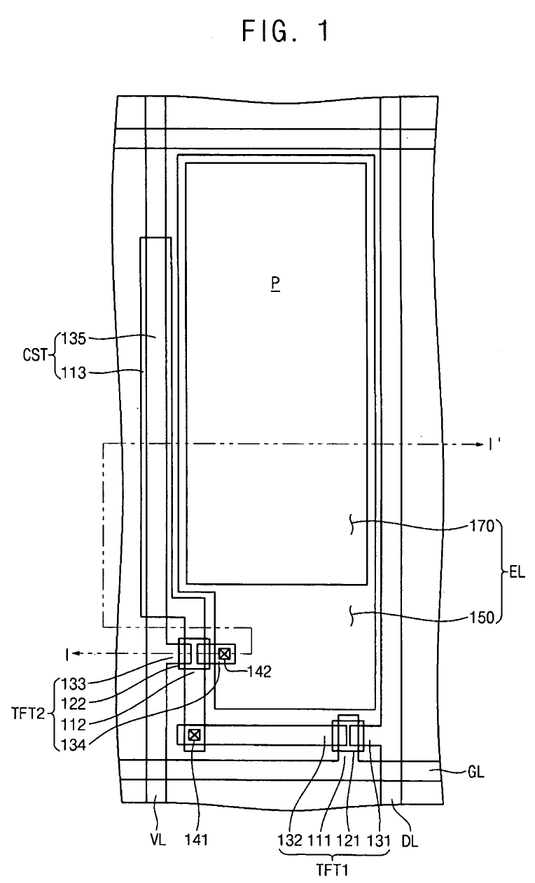

FIG. 1 is a layout illustrating a portion of an electroluminescent display substrate according to an example embodiment of the present invention.

Referring to FIG. 1, the electroluminescent display substrate includes a plurality of pixel regions ‘P’ defined by a plurality of source lines DL, a plurality of gate lines GL and a plurality of bias voltage lines VL.

The source lines DL and bias voltage lines VL extend in a first direction, and the gate lines GL extend in a second direction intersecting the first direction.

A first switching element TFT1, a second switching element TFT2, a storage capacitor CST and an electroluminescent element EL are formed in each of the pixel regions ‘P’.

The first switching element TFT1 includes a first gate electrode 111 electrically connected to one of the gate lines GL, a first source electrode 131 electrically connected to one of the source lines DL, and a first drain electrode 132 electrically connected to both of the storage capacitor CST and the second switching element TFT2. The first switching element TFT1 includes a first channel 121 formed between the first gate electrode 111 and one of the first source electrode 131 and the first drain electrode 132.

The second switching element TFT2 includes a second gate electrode 112 electrically connected to the first drain electrode 132, a second source electrode 133 electrically connected to one of the bias voltage lines VL, and a second drain electrode 134 electrically connected to the electroluminescent element EL. The second switching element TFT2 includes a second channel 122 formed between the second gate electrode 112 and one of the second source electrode 133 and the second drain electrode 134. The second switching element TFT2 drives the electroluminescent element EL.

The storage capacitor CST includes a first electrode 113 electrically connected to the second gate electrode 112 of the second switching element TFT2 and a second electrode 135 electrically connected to the one of the bias voltage lines VL.

The electroluminescent element EL includes a pixel electrode 150 electrically connected to the second drain electrode 134 of the second switching element TFT2, a common electrode (not shown) and an electroluminescent layer 170 disposed between the pixel electrode 150 and the common electrode.

Each of the pixels is operated as follows. A gate signal is applied to the first switching element TFT1 via one of the gate lines GL to turn on the first switching element TFT1. With the first switching element TFT1 turned on, a source signal via one of the source lines DL is applied to the second switching element TFT2 to turn on the second switching element TFT2. Since the first electrode 113 of the storage capacitor CST is electrically connected to the second gate electrode 112 of the second switching element TFT2, the second switching element TFT2 being turned on charges the storage capacitor CST.

When the second switching element TFT2 is turned on, the bias voltage of one of the bias voltage lines VL is applied to the electroluminescent element EL through the second switching element TFT2. Thus, the electroluminescent element EL emits light of a predetermined luminance level.

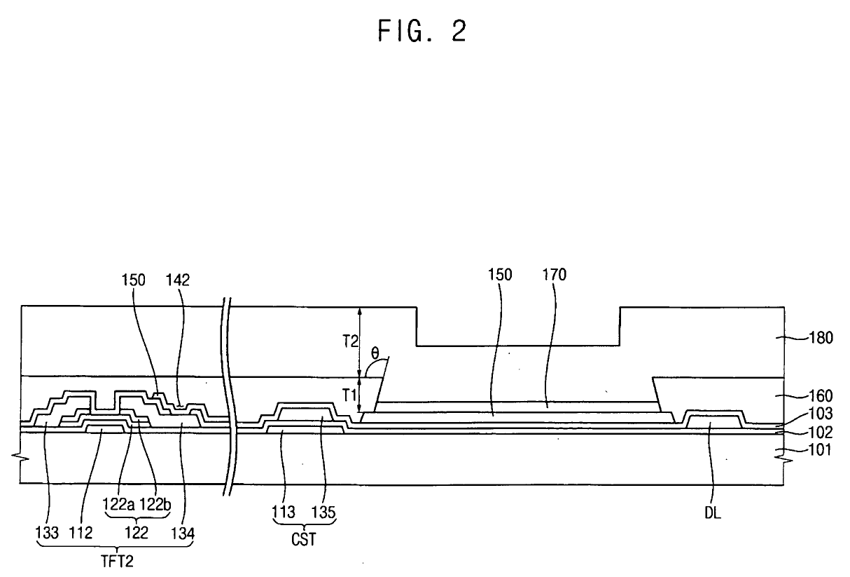

FIG. 2 is a cross-sectional view taken along a line I-I′ in FIG. 1.

Referring to FIGS. 1 and 2, the electroluminescent display substrate includes a base substrate 101. The source lines DL, the gate lines GL, the bias voltage lines VL, the first switching element TFT1, the second switching element TFT2, the storage capacitor CST and the electroluminescent element EL are formed on the base substrate 101. The first and second switching substrates TFT1 and TFT2 are amorphous silicon thin film transistors.

Particularly, the second switching element TFT2 includes the second gate electrode 112 formed on the base substrate 101, the second channel 122,formed on the second gate electrode 112, and the second source and drain electrodes 133 and 134 both formed on the second channel 122.

A gate insulation layer 102 is formed between the second gate electrode 112 and the second channel 122. A passivation layer 103 is formed on the second source and drain electrodes 133 and 134.

The first electrode 113 formed on the base substrate 101, a portion of the gate insulation layer 102 formed on the first electrode 113, and the second electrode 135 formed on the gate insulation layer 102 define the storage capacitor CST. The passivation layer 103 is formed on the second electrode 135.

The electroluminescent element EL includes the pixel electrode 150 formed on the base substrate 101. The gate insulation layer 102 and the passivation layer 103 are successively formed on the base substrate 101, the pixel electrode 150 is formed on the passivation layer 103, the electroluminescent layer 170 is formed on the pixel electrode 150, and the common electrode 180 is formed on the electroluminescent layer 170. The pixel electrode 150 and the common electrode 180 correspond to an anode and a cathode of the electroluminescent element EL, respectively.

The electroluminescent layer 170 includes at least one of a hole-injection layer, a hole-transport layer, a light-emitting layer, an electron-injection layer and an electron-transport layer. The electroluminescent layer 170 is formed on the pixel electrode 150 in a light-emitting area defined by a bank 160. The bank 160, for example, is formed by using a negative type photoresist, and a side surface of the bank 160 is slanted so as to form an angle θ with respect to an upper surface of the bank 160 as shown in FIG. 2.

The common electrode 180 is formed through an ink jet printing method using a nanopaste. The common electrode 180 has a second thickness T2 that is greater than a first thickness T1 of the bank 160. The second thickness T2 of the common electrode 180 ranges from about 0.3 μm to about 10 μm.

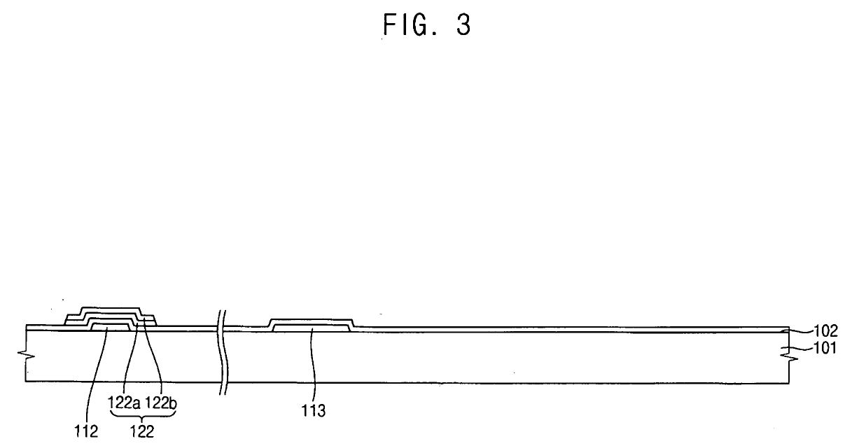

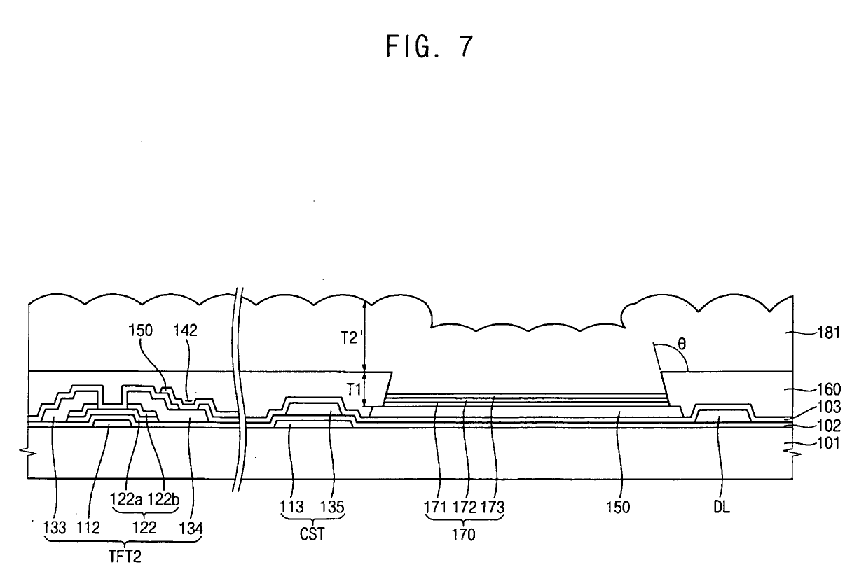

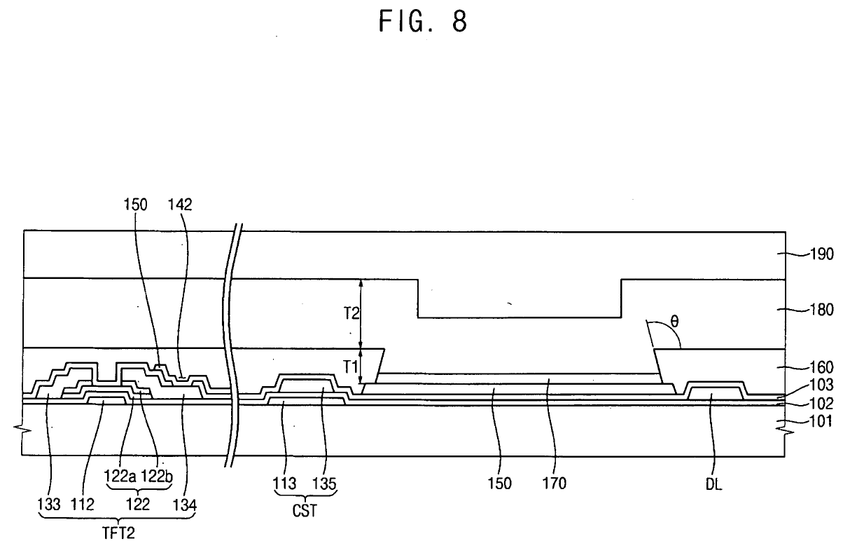

FIGS. 3 to 8 are cross-sectional views illustrating a method of manufacturing the electroluminescent display substrate shown in FIG. 2.

Referring to FIGS. 1 and 3, the electroluminescent display substrate includes a base substrate 101. The base substrate 101, for example, includes glass, sapphire or transparent synthetic resin such as polyester, polyacrylate, polycarbonate, polyetherketone, etc.

A gate metal layer is deposited on the base substrate 101 and patterned to form gate metal patterns. The gate metal layer is a conductive layer including, for example, at least one of chromium (Cr), aluminum (Al), tantalum (Ta), molybdenum (Mo), titanium (Ti), tungsten (W), copper (Cu), silver (Ag), etc. The conductive layer is deposited through a sputtering process and patterned to form the gate metal patterns.

The gate metal patterns include the gate lines GL, the first gate electrode 111 of the first switching element TFT1, the second gate electrode 112 of the second switching element TFT2, and the first electrode 113 of the storage capacitor CST. The gate insulation layer 102 is formed on the base substrate 101 having the gate metal patterns. The gate insulation layer 102, for example, includes silicon oxide or silicon nitride.

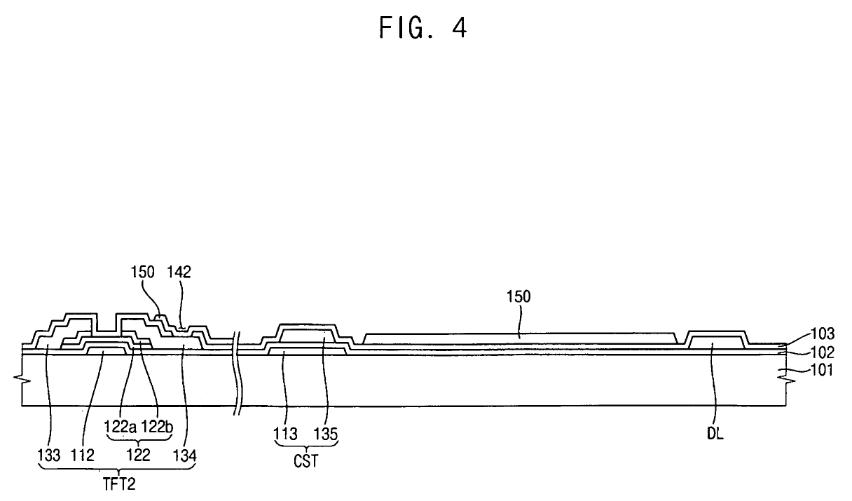

Referring to FIGS. 1 and 4, the first and second channels 121 and 122 are formed on the base substrate 101 having the gate insulation layer 102. An active layer 122a and an ohmic contact layer 122b are successively deposited and patterned to form the second channel 122.

Particularly, an amorphous silicon layer and an in-situ doped n+ amorphous silicon layer are successively deposited on the gate insulation layer 102 through a chemical vapor deposition (CVD) process. The deposited amorphous silicon layer and n+ amorphous silicon layer are patterned to form the active layer 122a and the ohmic contact layer 122b, respectively, over the second gate electrode 112.

A source metal layer is deposited and patterned on the base substrate 101 having the first and second channels 121 and 122 to form source metal patterns. The source metal layer that is a conductive layer including, for example, at least one of chromium (Cr), aluminum (Al), tantalum (Ta), molybdenum (Mo), titanium (Ti), tungsten (W), copper (Cu), silver (Ag), etc. is deposited through a sputtering process, and patterned to form the source metal patterns.

The source metal patterns include the source lines DL, the first and second source electrodes 131 and 133, the first and second drain electrodes 132 and 134, and the second electrode 135 of the storage capacitor CST.

The passivation layer 103 is formed on the base substrate 101 having the source metal patterns. A portion of the passivation layer 103 is removed to form a second contact hole 142 exposing a portion of the second drain electrode 134.

A transparent conductive material, such as indium tin oxide (ITO) or indium zinc oxide (IZO), is deposited and patterned to form a pixel electrode 150. The pixel electrode 150 is formed in each of the pixel regions ‘P’ defined by one of the source lines DL, one of the bias voltage lines VL and neighboring gate lines GL.

The pixel electrode 150 is electrically connected to the second drain electrode 134 through the second contact hole 142. The pixel electrode 150 corresponds to the anode of the electroluminescent element EL.

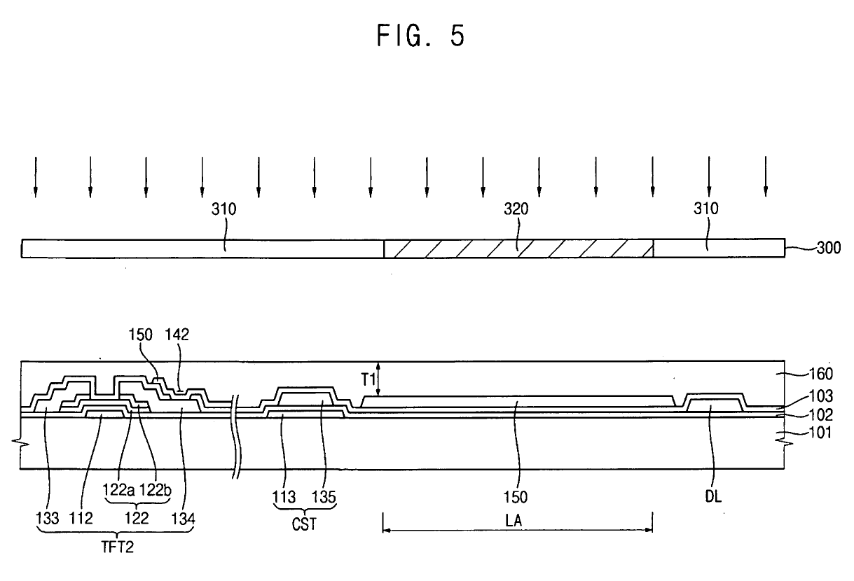

Referring to FIGS. 1 and 5, the bank 160 is formed on the base substrate 101 having the first and second switching elements TFT1 and TFT2, and the pixel electrode 150. The bank 160, for example, includes a negative type photoresist and has a first thickness T1. The first thickness T1 is in a range of about 300 nm to about 5000 nm.

The bank 160 is patterned by using a mask 300 that includes an opening portion 310 and a light-blocking portion 320. The opening portion 310 and the light-blocking portion 320 define a non-light-emitting area and a light-emitting area, respectively.

The portion of the bank 160 that is defined by the opening portion 310 is cured through an exposure process. In contrast, the portion of the bank 160 that is defined by the light-blocking portion 320 is not cured through the exposure process. The portion of the bank 160 that is defined by the light-blocking portion 320 is etched to define the light-emitting area LA in each of the pixel regions ‘P’.

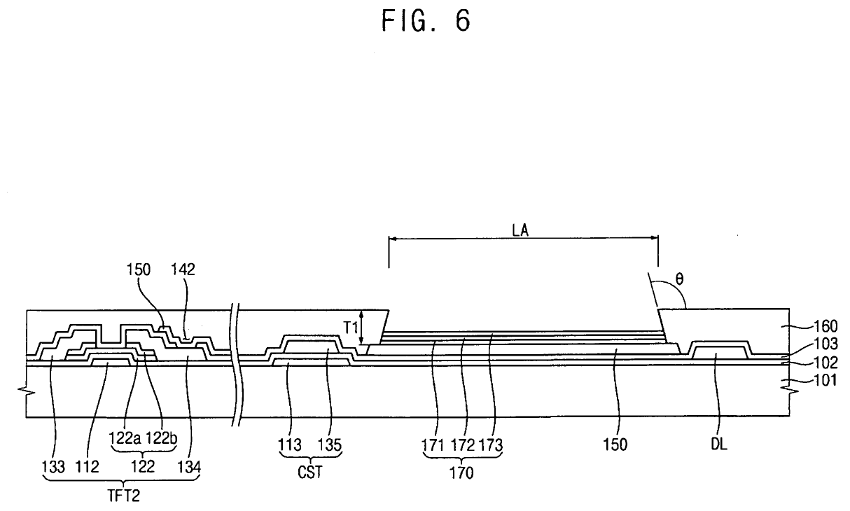

Referring to FIGS. 1 and 6, the portion of the bank 160 is etched to form the light-emitting area LA. Since the bank 160 includes a negative type photoresist, the portion of the bank 160, which corresponds to the light-blocking portion 320 of the mask 300, is removed such that a side surface of the bank 160 forms an angle θ with respect to the upper surface of the bank 160. The angle θ, for example, is in a range of about ninety degrees to about one hundred seventy degrees.

Then, a lyophilic area and a lyophobic area are formed on a surface of the bank 160 through a plasma treatment process. The lyophilic area has a relatively large surface energy, and the lyophobic area has a relatively small surface energy.

In detail, the plasma treatment process includes a lyophilization process and a lyophobization process. The side surface of the bank 160 and an upper surface of the pixel electrode 150 are lyophilized through the lyophilization process. The upper surface of the bank 160 is lyophobized through the lyophobization process. To perform the lyophilization process, the base substrate 101 having the bank 160 is heated to a predetermined temperature. Next, a plasma treatment such as the lyophilization process is performed in an atmospheric environment by using oxygen (O₂) as a reaction gas.

Then, a plasma treatment such as the lyophobization process is performed in an atmospheric environment by using tetrafluoromethane (CF₄) as a reaction gas. Thereafter, the base substrate 101 that was previously heated for the plasma treatment is cooled. This way, the lyophilic area and the lyophobic area are formed on the base substrate 101 having the bank 160.

The electroluminescent layer 170 is formed in the light-emitting area LA defined by the bank 160 through a solution processing. Examples of the solution processing may include spin coating, dip coating and ink jet printing methods.

The electroluminescent layer 170 includes a hole-transport layer (HTL) and a light-emitting layer (EML). The electroluminescent layer 170 optionally includes at least one of an electron-transport layer (ETL), an electron-injection layer (EIL), a hole-injection layer (HIL) and a hole-blocking layer (HBL) to improve characteristics of the electroluminescent element EL.

In detail, a hole-injection/transport layer (HIL/HTL) 171, a light-emitting layer (EML) 172 and an electron-injection/transport layer (EIL/ETL) 173 are successively formed on the pixel electrode within the light-emitting area LA by an ink jet printing method.

The hole-transport layer is formed, for example, using polyethylene dioxythiophene, triphenyl anyl derivatives, pyrazoline derivatives, aryl amine derivatives, stilbene derivatives, triphenyl diamine derivatives, etc.

Depending on the embodiment, a hole-injection layer may be formed instead of the hole-transport layer, or both of the hole-injection layer and the hole-transport layer may be formed. Further, one or more layers for improving the characteristics of electroluminescent element EL may be formed separately or simultaneously with the hole-injection layer and/or the hole-transport layer.

The light-emitting layer may include a low molecular weight organic light-emitting material or a high molecular weight organic light-emitting material, such as a light-emitting material containing a fluorescent substance or a phosphorescent substance. Examples of high molecular weight fluorescent substances include polyfluorene and polyphenylenevinylene. Examples of low molecular weight fluorescent substances include naphthalene derivatives, anthracene derivatives, perylene derivatives and polymethine group.

The electron-transport layer is formed using, for example, diazo derivatives, benzoquinone and derivatives, naphthoquinone and derivatives, etc.

Alternatively, the electroluminescent layer 170 is not limited to the above materials, but may include various materials.

Referring to FIGS. 1, 7 and 8, the common electrode 180 having the second thickness T2 is formed on the base substrate 101 having the electroluminescent layer 170. The second thickness T2 is thicker than the first thickness T1 of the bank 160.

In detail, the common electrode 180 includes an electrically conductive nanopaste having a metal nanoparticle. The metal nanoparticle may include at least one of silver (Ag), gold (Au), nickel (Ni), indium (In), tin (Sn), zinc (Zn), lead (Pb), titanium (Ti), copper (Cu), chromium (Cr), tantalum (Ta), tungsten (W), palladium (Pd), platinum (Pt), iron (Fe), cobalt (Co), boron (B), silicon (Si), aluminum (Al), magnesium (Mg), rubidium (Rb), iridium (Ir), vanadium (V), ruthenium (Ru), osmium (Os), niobium (Nb), bismuth (Bi), barium (Ba), etc. In some embodiments, the metal nanoparticle may include an alloy of the above metals. Alternatively, the metal nanoparticle may include silver oxide, copper oxide, etc.

Examples of a solvent for making the metal nanoparticle into a paste may include deionized water, an alcohol such as ethanol, butanol, ethylene glycol, terpineol, citronelol, geraniol, penethyl alcohol, etc., an ester such as acetic acid ethyl ester, oleic acid methyl ester, acetic acid butyl ester, glyceride, etc., and a mixture thereof.

A preliminary common electrode 181 having a predetermined thickness T2′ that is thicker than the first thickness T1 of the bank 160 is formed on the base substrate 101 having the electroluminescent layer 170 using the metal nanopaste by the solution processing.

The preliminary common electrode 181 having the predetermined thickness T2′ may be formed by an ink jet printing method. Thus, the preliminary common electrode 181 may be thicker than the common electrode, which is formed by a sputtering process. Since the preliminary common electrode 181 does not have an overspill problem with the above-mentioned structure, it lends itself to being formed by the ink jet printing method.

As described above, a thick preliminary common electrode 181 may be easily formed using the metal nanopaste with the ink jet printing method. As the preliminary common electrode 181 can be made thick enough to compensate for the height difference between the bank 160 and the EL layer 170, the preliminary common electrode 181 is formed continuously in spite of a stepped portion of the bank 160.

The preliminary common electrode 181 that is made with the metal nanopaste is cured to form the common electrode 180. In detail, the base substrate 101 on which the metal nanopaste is jetted is dried and cured using an infrared light or a hot wind to form the common electrode 180. The drying and curing process may be performed under a relatively low temperature to prevent any damage to the other elements formed on the base substrate 101.

The common electrode 180 having the second thickness T2 that is greater than the first thickness of the bank 160 is formed on the base substrate 101 through the drying and curing process, as mentioned above. The second thickness T2 is in a range of about 300 nm to about 10,000 nm. An adhesive material (not shown) including a photopolymer is then coated on the base substrate 101 with the common electrode 180. The coated adhesive material is not in a cured state.

Then, silicon oxide is deposited on the common electrode 180 to form an inorganic protective layer, and epoxy resin is coated on the inorganic protective layer to form an organic protective layer. Thus, a protective layer 190 including the inorganic protective layer and the organic protective layer is formed on the common electrode 180.

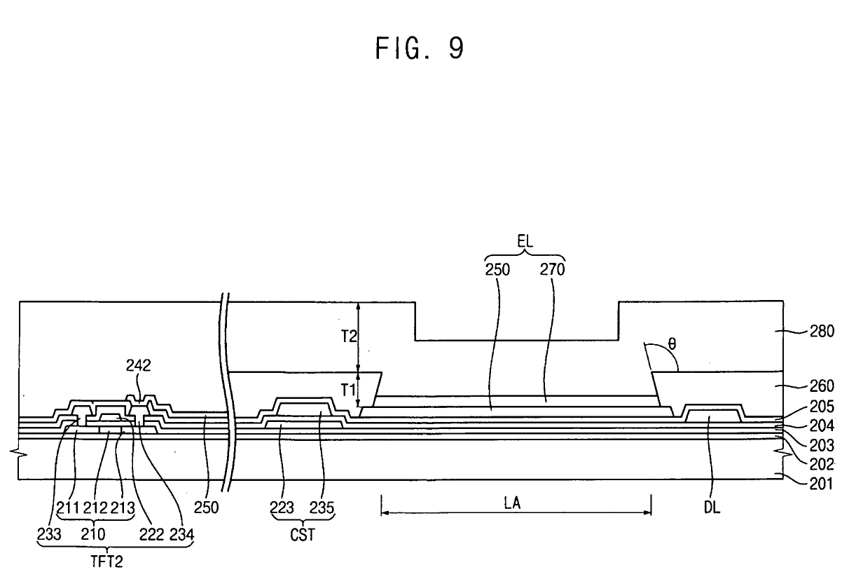

FIG. 9 is a cross-sectional view illustrating an electroluminescent display substrate according to another embodiment of the present invention.

Referring to FIG. 9, a buffer insulation layer 202 is formed on a base substrate 201. The buffer insulation layer 202 may contain one or more of silicon nitride, silicon oxide, etc. A first switching element (not shown) and a second switching element TFT2 are formed on the buffer insulation layer 202.

In detail, the second switching element TFT2 is formed on the base substrate 202 as follows. An amorphous silicon layer is formed on the buffer insulation layer 202. The amorphous silicon layer is crystallized to form a polysilicon layer 210 through an annealing process. The crystallized polysilicon layer 210 is patterned, and a gate insulation layer 203 is formed on the patterned polysilicon layer 210.

A gate metal layer is deposited and patterned on the gate insulation layer 203 to form gate metal patterns.

The gate metal patterns include a first gate electrode (not shown) of the first switching element, a second gate electrode 222 of the second switching element TFT2, a first electrode 223 of a storage capacitor CST and gate lines (not shown). The gate metal patterns are formed in a single metal layer as shown in FIG. 9. However, in other embodiments, the gate metal patterns may be formed in multiple metal layers such as double or triple metal layers.

Thus, the second gate electrode 222 is formed on the gate insulation layer 203.

A dopant is injected into the polysilicon layer 210 by using the second gate electrode 222 as a mask. Thus, the polysilicon layer 210 is formed as a channel layer 212 and doped layers 211 and 213. Doped ions in the doped layers 211 and 213 are activated through an annealing process.

An insulation material such as silicon oxide, silicon nitride, etc. is deposited on the base substrate 201 having the gate metal patterns to form a first insulation layer 15 204. The gate insulation layer 203 and the first insulation layer 204 are partially removed such that the doped layers 211 and 213 are partially exposed, thereby forming contact holes.

Then, a source metal layer is deposited and patterned on the first insulation layer 204 having the contact holes to form source metal patterns. The source metal patterns include a first source electrode (not shown) and a first drain electrode (not shown) of the first switching element, a second source electrode 233 and a second drain electrode 234 of the second switching element TFT2, a second electrode 235 of the storage capacitor CST and source lines DL.

Thus, the doped layers 211 and 213 are electrically connected to the second source electrode 233 and the second drain electrode 234, respectively.

A second insulation layer 205 is formed on the base substrate 201 having the source metal patterns. A planarization layer may be formed on the second insulation layer 205.

The second insulation layer 205 is partially removed to form a second contact hole 242 that exposes the second drain electrode 234. A transparent conductive material such as indium tin oxide (ITO), indium zinc oxide (IZO), etc. is deposited and patterned on the base substrate 201 having the second contact hole 242 to form a pixel electrode 250.

The pixel electrode 250 is electrically connected to the second drain electrode 234 through the second contact hole 242. The pixel electrode 250 corresponds to an anode of an electroluminescent element EL.

A bank 260 is formed on the base substrate 201 having the first switching element, the second switching element TFT2 and the pixel electrode 250 by using a negative-type photoresist. The bank 260 has a first thickness that is in a range of about 300 nm to about 5,000 nm.

The bank 260 defines a light-emitting area LA in a region where the pixel electrode 250 is formed. Since the bank 260 includes a negative-type photoresist, the portion of the bank 260 that corresponds to the light-blocking portion of a mask is removed such that a side surface of the bank 260 forms an angle θ with respect to the upper surface of the bank 260. The angle θ, for example, is in a range of about ninety degrees to about one hundred seventy degrees.

A lyophilic area and a lyophobic area are formed on a surface of the bank 260 through a plasma treatment process.

The electroluminescent layer 270 is formed in the light-emitting area LA defined by the bank 260 through solution processing. Examples of solution processing may include spin coating, dip coating, and ink jet printing. The electroluminescent layer 270 includes a hole-injection layer (HIL), a hole-transport layer (HTL), a light-emitting layer (EML), an electron-injection layer (EIL) and an electron-transport layer (ETL).

A cathode 280 having the second thickness T2 is formed on the base substrate 201 having the electroluminescent layer 270. The second thickness T2 is thicker than the first thickness T1 of the bank 260. The second thickness T2 is in a range of about 300 nm to about 10,000 nm.

In detail, the cathode 280 includes an electrically conductive nanopaste containing a metal nanoparticle. The metal nanoparticle may include at least one of silver (Ag), gold (Au), nickel (Ni), indium (In), tin (Sn), zinc (Zn), lead (Pb), titanium (Ti), copper (Cu), chromium (Cr), tantalum (Ta), tungsten (W), palladium (Pd), platinum (Pt), iron (Fe), cobalt (Co), boron (B), silicon (Si), aluminum (Al), magnesium (Ma), rubidium (Rb), iridium (Ir), vanadium (V), ruthenium (Ru), osmium (Os), niobium (Nb), bismuth (Bi), barium (Ba), etc. In some embodiments, the metal nanoparticle may include an alloy of the above metals. Alternatively, the metal nanoparticle may include silver oxide, copper oxide, etc.

Examples of an organic solvent for making the metal nanoparticle into a paste may include deionized water, an alcohol such as ethanol, butanol, ethylene glycol, terpineol, citronellol, geraniol, penethyl alcohol, etc., an ester such as acetic acid ethyl ester, oleic acid methyl ester, acetic acid butyl ester, glyceride, etc., and a mixture thereof.

The above metal nanopaste is deposited on the base substrate 201 with the electroluminescent layer 270 by using the ink jet printing method. By using the ink jet printing method, the metal nanopaste can be deposited to a greater thickness than the bank 260, thereby forming the cathode 280. By using the metal nanopaste, the cathode 280 may be formed thick enough to compensate for the height difference between the EL layer 270 and the bank 260, allowing the cathode 280 to form continuously in spite of a stepped portion created by the bank 260.

The metal nanopaste is jetted on base substrate 201, then dried and cured using an infrared light or a hot wind. This way, the cathode having the second thickness T2 that is thicker than the first thickness T1 of the bank 260 is formed.

As described above, the sufficiently thick cathode 280 may be easily formed using the metal nanopaste with the ink jet printing method. This way, the stepped portion formed by the height difference between the EL layer 270 and the bank 260 does not cause a discontinuity in the formation of the thick cathode 181.

According to the present invention, a cathode (or the common electrode) of an electroluminescent element is formed thicker than the bank that defines a light-emitting area of an electroluminescent display substrate.

In addition, the cathode is formed using a metal nanopaste to achieve the desired thickness.

Thus, the invention improves the manufacturing efficiency and reliability of the electroluminescent display substrate.

Although the example embodiments of the present invention have been described, it is understood that the present invention should not be limited to these example embodiments but various changes and modifications can be made by one ordinary skilled in the art within the spirit and scope of the present invention as hereinafter claimed.

What is claimed is:

1. A light-emitting element comprising:
a first electrode formed on a base substrate;
a bank formed on the first electrode to define a light-emitting area, the bank having a first thickness;
a light-emitting layer formed on a part of the first electrode that is in the light-emitting area; and
a second electrode formed on the light-emitting layer, the second electrode having a second thickness that is greater than the first thickness of the bank.

2. The light-emitting element of claim 1, wherein the second electrode includes an electrically conductive nanopaste containing a metal nanoparticle.

3. The light-emitting element of claim 1, wherein the bank includes a negative-type photoresist.

4. The light-emitting element of claim 1, wherein the bank has a side wall that makes an angle of about 90 degrees to about 170 degrees with respect to an outer surface of the bank.

5. The light-emitting element of claim 1, wherein the first thickness of the bank is in a range of about 300 nm to about 5,000 nm.

6. The light-emitting element of claim 1, wherein the second thickness of the second electrode is in a range of about 300 nm to about 10,000 nm.

7. The light-emitting element of claim 1, wherein the first electrode corresponds to an anode, and the second electrode corresponds to a cathode.

8. A method of manufacturing a light-emitting element comprising:
forming a first electrode on a base substrate;
forming a bank on the first electrode to define a light-emitting area, the bank having a first thickness;
forming a light-emitting layer on a part of the first electrode that is in the light-emitting area; and
forming a second electrode on the light-emitting layer, the second electrode having a second thickness that is greater than the first thickness of the bank.

9. The method of claim 8, wherein the second electrode is formed by using a nanopaste containing a metal nanoparticle.

10. The method of claim 9, wherein the second electrode is formed by:
ejecting the nanopaste; and
curing the ejected nanopaste.

11. The method of claim 8, wherein the bank is formed by using a negative-type photoresist.

12. The method of claim 8, wherein the bank has a sidewall that forms an angle of about 90 degrees to about 170 degrees with respect to an outer surface of the bank.

13. The method of claim 8, wherein the first thickness of the bank is in a range of about 300 nm to about 5,000 nm.

14. The method of claim 8, wherein the second thickness of the second electrode is in a range of about 300 nm to about 10,000 nm.

15. The method of claim 8, wherein the light-emitting layer is formed by a solution processing.

16. The method of claim 8, wherein the first electrode corresponds to an anode, and the second electrode corresponds to a cathode.

17. A display substrate having a pixel region defined by a source line, a bias voltage line and neighboring gate lines, comprising:
a first switching element electrically connected to the bias voltage line;
a first electrode formed in the pixel region and electrically connected to the first switching element;
a bank formed on a portion of the first electrode to define a light-emitting area in the pixel region, the bank having a first thickness;
a light-emitting layer formed on the first electrode of the light-emitting area; and
a second electrode formed on the light-emitting layer, the second electrode having a second thickness that is thicker than the first thickness of the bank.

18. The display substrate of claim 17, further comprising a second switching element electrically connected to the source line and one of the gate lines, wherein the first switching element is controlled by a second switching element.

19. The display substrate of claim 17, wherein the second electrode includes an electrically conductive nanopaste containing a metal nanoparticle.

20. The display substrate of claim 17, wherein the second thickness of the second electrode is in a range of about 300 nm to about 10,000 nm.

21. The display substrate of claim 17, wherein the bank has a side wall that forms an angle greater than 90° with respect to an outer surface of the bank.

22. The display substrate of claim 17, wherein the first and second switching element comprise an amorphous silicon thin film transistor.

23. The display substrate of claim 17, wherein the first switching element comprise a polysilicon thin film transistor.

24. A light-emitting element comprising:
a first electrode formed on a base substrate;
a bank formed on the first electrode to define a light-emitting area, the bank including a negative-type photoresist;
a light-emitting layer formed on the first electrode of the light-emitting area; and
a second electrode formed on the light-emitting layer, the second electrode including an electrically conductive nanopaste containing a metal nanoparticle.
